(19) United States
(12) Patent Application Publication
(10) Pub. No.: US 2024/0332371 A1
(43) Pub. Date: Oct. 3, 2024

(54) EPITAXIAL STRUCTURE OF SEMICONDUCTOR DEVICE AND PREPARING METHOD THEREOF, AND SEMICONDUCTOR DEVICE

(71) Applicant: Dynax Semiconductor, Inc., Suzhou (CN)

(72) Inventors: Hui ZHANG, Suzhou (CN); Susu KONG, Suzhou (CN)

(73) Assignee: Dynax Semiconductor, Inc., Suzhou (CN)

(21) Appl. No.: 18/738,233

(22) Filed: Jun. 10, 2024

Related U.S. Application Data
(63) Continuation of application No. PCT/CN2022/141348, filed on Dec. 23, 2022.

(30) Foreign Application Priority Data
Dec. 24, 2021 (CN) 202111598873.3

(51) Int. Cl. H01L 29/20; H01L 21/02; H01L 21/768

(52) U.S. Cl. CPC H01L 29/2003; H01L 21/02458; H01L 21/76871

(57) ABSTRACT

An epitaxial structure of a semiconductor device includes a substrate, a nucleation layer and a buffer layer. The nucleation layer is located at a side of the substrate, the nucleation layer includes a plurality of nucleation units, surfaces, close to the substrate, of the plurality of nucleation units are communicated with each other, and surfaces, away from the substrate, of the plurality of nucleation units are separated from each other; and the buffer layer is located at a side, away from the substrate, of the nucleation layer, the buffer layer includes a 3D buffer layer, and the 3D buffer layer is formed on a surface, away from the substrate, of the nucleation layer. In the technical solutions of the present disclosure, quality of an epitaxial structure may be improved, ensuring quality of a semiconductor device.

### CROSS-REFERENCE TO RELATED APPLICATIONS

The present disclosure is a continuation of International Application No. PCT/CN2022/141348, filed on Dec. 23, 2022, which claims priority to Chinese Patent Application No. 202111598873.3, filed on Dec. 24, 2021. The disclosures of the aforementioned applications are hereby incorporated by reference in their entireties.

### TECHNICAL FIELD

The present disclosure relates to the field of semiconductor technologies, and in particular, to an epitaxial structure of a semiconductor device and a preparing method thereof, and a semiconductor device.

### BACKGROUND

Gallium nitride (GaN) in semiconductor materials is more suitable than silicon (Si) and gallium arsenide (GaAs) for preparing devices with high-temperature, high-frequency, high-voltage and high-power, such as a High Electron Mobility Transistor (HEMT) prepared by the GaN, because of its characteristics such as a wide band gap, a high electron saturation drift speed, a high breakdown field strength and a good thermal conductivity.

However, due to lack of a GaN substrate, the GaN is usually grown on a heterogeneous substrate in a GaN epitaxial technology. There is a lattice mismatch between the GaN and the heterogeneous substrate, which leads to more penetrating dislocations in heterogeneous epitaxial GaN materials, affecting crystal quality of the GaN, and further affecting quality of a semiconductor device.

### SUMMARY

Embodiments of the present disclosure provide an epitaxial structure of a semiconductor device and a preparing method thereof, and a semiconductor device, to improve quality of an epitaxial structure, thereby ensuring quality of a semiconductor device.

In a first aspect, embodiments of the present disclosure provide an epitaxial structure of a semiconductor device, including: a substrate; a nucleation layer located at a side of the substrate, the nucleation layer including a plurality of nucleation units, surfaces, close to the substrate, of the plurality of nucleation units being communicated with each other, and surfaces, away from the substrate, of the plurality of nucleation units being separated from each other; and a buffer layer located at a side, away from the substrate, of the nucleation layer, the buffer layer including a three-dimensional (3D) buffer layer, and the 3D buffer layer is formed on a surface, away from the substrate, of the nucleation layer.

In one embodiment, a first cross section of a nucleation unit is perpendicular to a plane where the substrate is located, and a shape of the first cross section is trapezoid.

In one embodiment, the first cross section includes a first edge and a second edge along a direction perpendicular to a plane where the substrate is located, the first edge is located at a side, away from the substrate, of the second edge, a length of the first edge is P1, and a length of the second edge is P2, where 1<P2/P1≤3; and a distance between the first edge and the second edge is T1, where 10 nm≤T1≤100 nm. For example, T1 is equal to a value of 10 nm, 20 nm, 30 nm, 40 nm, 50 nm, 60 nm, 70 nm, 80 nm, 90 nm or 100 nm, or any point value in a range consisted of two endpoints, and the two endpoints are any values above-mentioned.

In one embodiment, the buffer layer further includes a two-dimensional (2D) buffer layer, and the 2D buffer layer is located at a side, away from the nucleation layer, of the 3D buffer layer.

In one embodiment, along a direction perpendicular to a plane where the substrate is located, a thickness of the 3D buffer layer is T2, and a thickness of the 2D buffer layer is T3, where ¼≤T2/(T2+T3)≤½.

In one embodiment, 0.1 μm≤T2+T3≤10 μm. For example, T2+T3 is equal to a value of 0.1 μm, 0.3 μm, 0.5 μm, 0.7 μm, 0.9 μm, 1 μm, 2 μm, 3 μm, 4 μm, 5 μm, 6 μm, 7 μm, 8 μm, 9 μm or 10 μm, or any point value in a range consisted of two endpoints, and the two endpoints are any values above-mentioned.

In one embodiment, the 3D buffer layer is grown directly along a direction perpendicular to a plane where the substrate is located.

In one embodiment, the 2D buffer layer is first grown in 2D along a direction parallel to a plane where the substrate is located to form a planar thin film, and then is grown in stacks along a direction perpendicular to the plane where the substrate is located.

In one embodiment, the plurality of nucleation units are island-shaped.

In one embodiment, a material of the substrate is selected from one or more combinations of indium phosphide, gallium arsenide, silicon carbide, diamond, sapphire, germanium, silicon or a material that is heterogeneous with GaN and capable to grow group III nitrides.

In a second aspect, embodiments of the present disclosure also provide a preparing method for an epitaxial structure of a semiconductor device, configured to prepare the epitaxial structure provided in the first aspect, including: providing a substrate; forming a nucleation layer on a side of the substrate, the nucleation layer including a plurality of nucleation units, surfaces, close to the substrate, of the plurality of nucleation units being communicated with each other, and surfaces, away from the substrate, of the plurality of nucleation units being separated from each other; and forming a buffer layer on a side, away from the substrate, of the nucleation layer, the buffer layer including a 3D buffer layer, and the 3D buffer layer being formed on a surface, away from the substrate, of the nucleation layer.

In one embodiment, the forming a nucleation layer on a side of the substrate includes: forming the nucleation layer with a first thickness on the side of the substrate at a first temperature and a first pressure, and the first thickness is a thickness along a direction perpendicular to a plane where the substrate is located; and the first temperature ranges from 1050° C. to 1200° C., the first pressure ranges from 50 mbar to 150 mbar, and the first thickness ranges from 10 nm to 100 nm. For example, the first thickness is equal to a value of 10 nm, 20 nm, 30 nm, 40 nm, 50 nm, 60 nm, 70 nm, 80 nm, 90 nm or 100 nm, or any point value in a range consisted of two endpoints, and the two endpoints are any values above-mentioned.

In one embodiment, the forming a buffer layer on a side, away from the substrate, of the nucleation layer includes: forming the 3D buffer layer on the side, away from the substrate, of the nucleation layer at a second temperature and a second pressure; and the second temperature ranges from 1000° C. to 1080° C., and the second pressure ranges from 150 mbar to 600 mbar.

In one embodiment, the buffer layer further includes a 2D buffer layer; and the forming a buffer layer on a side, away from the substrate, of the nucleation layer includes: forming the 2D buffer layer on a side, away from the nucleation layer, of the 3D buffer layer at a third temperature and a third pressure; and the third temperature ranges from 1000° C. to 1080° C., and the third pressure ranges from 50 mbar to 150 mbar.

In a third aspect, embodiments of the present disclosure further provide a semiconductor device including the epitaxial structure provided by the first aspect; and the semiconductor device further includes a heterojunction structure located at a side, away from the substrate, of the epitaxial structure, and a gate, a source and a drain located at a side, away from the substrate, of the heterojunction structure, and the gate is located between the source and the drain.

In the epitaxial structure of the semiconductor device provided by the embodiments of the present disclosure, the nucleation layer is set to include the plurality of nucleation units that are island-shaped, the surfaces, close to the substrate, of each of the plurality of nucleation units are communicated with each other, and the surfaces, away from the substrate, of each of the plurality of nucleation units are separated from each other, which is beneficial to growth of the 3D buffer layer to ensure that a film is formed during the growth of the 3D buffer layer, so that dislocations may be bent and annihilated during 3D growth of the buffer layer, improving crystal quality of GaN, and further ensuring quality of a semiconductor device.

### BRIEF DESCRIPTION OF THE DRAWINGS

FIG. 1 is a schematic structural diagram of an epitaxial structure of a semiconductor device according to an embodiment of the present disclosure.

FIG. 2 is a schematic structural diagram of another epitaxial structure of a semiconductor device according to an embodiment of the present disclosure.

FIG. 3 to FIG. 5 are schematic diagrams showing a principle that an epitaxial structure of a semiconductor device according to an embodiment of the present disclosure has a small degree of warping.

FIG. 6 is a flowchart of a preparing method for an epitaxial structure of a semiconductor device according to an embodiment of the present disclosure.

FIG. 7 to FIG. 9 are schematic diagrams of intermediate structures generated during a preparation process of the preparing method shown in FIG. 6.

FIG. 10 is a flowchart of another preparing method for an epitaxial structure of a semiconductor device according to an embodiment of the present disclosure.

FIG. 11 is a schematic structural diagram of a semiconductor device according to an embodiment of the present disclosure.

### DETAILED DESCRIPTION OF THE EMBODIMENTS

The present disclosure may be further described in details with reference to the drawings and embodiments. It may be understood that, the specific embodiments described herein are merely intended to explain the present disclosure, and are not intended to limit the present disclosure. In addition, it should be noted that, for the convenience of description, merely a part but not all structures related to the present disclosure are shown in the drawings, shapes and sizes of elements in the drawings do not reflect true proportions thereof, and purposes are merely to schematically illustrate the content of the present disclosure.

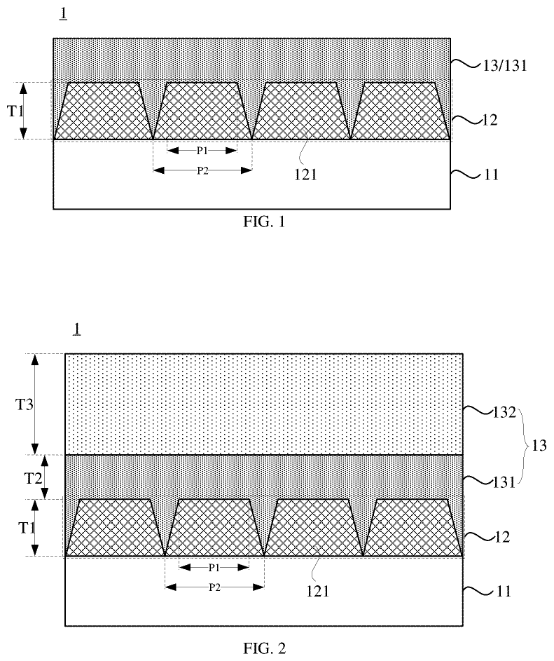

FIG. 1 is a schematic structural diagram of an epitaxial structure of a semiconductor device according to an embodiment of the present disclosure. As shown in FIG. 1, the epitaxial structure 1 of a semiconductor device provided by the embodiment of the present disclosure includes: a substrate 11, a nucleation layer 12 and a buffer layer 13. The nucleation layer 12 is located at a side of the substrate, the nucleation layer 12 includes a plurality of nucleation units 121 that are island-shaped, surfaces, close to the substrate 11, of each of the plurality of nucleation units 121 are communicated with each other, and surfaces, away from the substrate 11, of each of the plurality of nucleation units 121 are separated from each other. The buffer layer 13 is located at a side, away from the substrate 11, of the nucleation layer 12, the buffer layer 13 includes a 3D buffer layer 131, and the 3D buffer layer 131 is formed on a surface, away from the substrate 11, of the nucleation layer 12.

The epitaxial structure 1 provided by the embodiment of the present disclosure is applied to prepare a semiconductor device. Specifically, fabrication of the semiconductor device may be completed by forming a heterojunction structure (mainly including a barrier layer and a channel layer) by secondary growth on this epitaxial structure 1, and then forming a gate, a source and a drain on a side, away from the substrate 11, of the heterojunction structure. In the epitaxial structure 1, disposal of the buffer layer 13 may play a role in isolating the barrier layer from the substrate 11 while improving crystal quality. Therefore, improving quality of a buffer layer plays a crucial role in improving quality of a semiconductor device.

In this embodiment, the buffer layer 13 may specifically be a GaN buffer layer. As mentioned above, GaN has the characteristics such as a wide band gap, a high electron saturation drift speed, a high breakdown field strength and a good thermal conductivity, and is more suitable for preparing devices with high-temperature, high-frequency, high-voltage and high-power.

Further, in this embodiment, the buffer layer 13 includes the 3D buffer layer 131, and the 3D buffer layer 131 is formed on the surface, away from the substrate 11, of the nucleation layer 12. In other words, an initial growth mode of the buffer layer 13 is 3D growth. The so-called 3D growth refers to direct longitudinal growth of the buffer layer 13 in a direction perpendicular to a plane where the substrate 11 is located, so that grown GaN is island-shaped. Subsequently, with the increase of a thickness of the buffer layer 13, a distance between islands become smaller and smaller, and finally the islands merge into a film to form the 3D buffer layer 131 shown in FIG. 1. A mode of the 3D growth is to form a trapezoid or an island-shaped morphology first, and then the trapezoid or island-shaped morphology gradually grow to form a complete thin film. In the embodiments of the present disclosure, disposal of the 3D buffer layer 131 may play a role in improving crystal quality.

Further, in the epitaxial structure 1, disposal of the nucleation layer 12 may match a lattice between the substrate 11 and the buffer layer 13. In this embodiment, the nucleation layer 12 is set to include the plurality of nucleation units 121 that are island-shaped, the surfaces, close to the substrate 11, of each of the plurality of nucleation units 121 are communicated with each other, and the surfaces, away from the substrate 11, of each of the plurality of nucleation units 121 are separated from each other, which is more beneficial to 3D growth of the buffer layer 13. In this way, during the 3D growth of the buffer layer 13, dislocations, generated at an interface between the nucleation layer 12 and the substrate 11, and an interface between the nucleation layer 12 and the 3D buffer layer 131, may be bent and annihilated when extending along a growth direction. With the increase of a thickness of GaN, a dislocation density may be lower and lower, improving crystal quality of the GaN, and further ensuring quality of a semiconductor device.

Moreover, in this embodiment, the surfaces, close to the side of the substrate 11, of the nucleation units 121 are set to be in communication with each other, so that normal growth of the 3D buffer layer 131 may be ensured, avoiding the inability of the 3D buffer layer 131 to form a film. Reasons for the inability of the 3D buffer layer to form the film are that if the surfaces, close to the substrate 11, of the nucleation units 121 are not communicated with each other, a part of a surface of the substrate 11 may be exposed, while the buffer layer 13 cannot be grown on this exposed part of the substrate 11, resulting in the buffer layer 13 not being able to form the film. Specifically, a morphology of the nucleation layer 12 may be formed by adjusting process parameters, which is not explained in detail herein. Exemplarily, the nucleation layer 12 may specifically be an aluminum nitride (AIN) nucleation layer or an aluminum gallium nitride (AlGaN) nucleation layer, which is not limited by the embodiments of the present disclosure.

Optionally, a material of the substrate 11 may be one or more combinations of indium phosphide, gallium arsenide, silicon carbide, diamond, sapphire, germanium, silicon or a material that is heterogeneous with GaN and capable to grow group III nitrides, which is not limited by the embodiments of the present disclosure. The epitaxial structure 1 provided by the embodiments of the present disclosure is adopted, so that problems of a lattice mismatch between GaN and a heterogeneous substrate may be solved, improving crystal quality of GaN.

It should be noted that, in the epitaxial structure 1 of the semiconductor device provided by the embodiments of the present disclosure, the buffer layer 13 is not limited to merely including the 3D buffer layer 131, as long as the buffer layer 13 grown on the surface, away from the substrate 11, of the nucleation layer 12 is ensured to be the 3D buffer layer 131.

In conclusion, in the epitaxial structure 1 of the semiconductor device provided by the embodiments of the present disclosure, the nucleation layer 12 is set to include the plurality of nucleation units 121 that are island-shaped, the surfaces, close to the substrate 11, of each of the plurality of nucleation units 121 are communicated with each other, and the surfaces, away from the substrate, of each of the plurality of nucleation units 121 are separated from each other, which is beneficial to the growth of the 3D buffer layer 131 to ensure that a film is formed during the growth of the 3D buffer layer 131, so that dislocations may be bent and annihilated during 3D growth of the buffer layer 13, improving crystal quality of GaN, and further ensuring quality of a semiconductor device.

On the basis of the above embodiments, optionally, the nucleation unit 121 includes a first edge and a second edge along a direction perpendicular to a plane where the substrate 11 is located, the first edge is located at a side, away from the substrate, of the second edge, a length of the first edge is P1, and a length of the second edge is P2, which satisfies 1<P2/P1≤3, so that the islands in the nucleation layer 12 tend to merge, making it easy to form a film finally. Along the direction perpendicular to the plane where the substrate 11 is located, a distance between the first edge and the second edge is T1, which satisfies 10 nm≤T1≤100 nm, avoiding premature merging of the nucleation units to form a film, and providing a space for growth of the 3D buffer layer 131. Exemplarily, with continued reference to FIG. 1, a first cross section (such as a profile shown in the figures) is perpendicular to the plane where the substrate 11 is located. Optionally, a shape of the first cross section of the nucleation unit 121 is trapezoid. The trapezoid includes a first edge and a second edge along the direction perpendicular to the plane where the substrate 11 is located, the first edge is located at a side, away from the substrate 11, of the second edge, a length of the first edge is P1, a length of the second edge is P2, and along the direction perpendicular to the plane where the substrate 11 is located, a height of the trapezoid is T1, which satisfies 1<P2/P1≤3 and 10 nm≤T1≤100 nm.

It should be understood that the thickness mentioned in the embodiments of the present disclosure refers to a distance along the direction perpendicular to the plane where the substrate 11 is located.

Specifically, the nucleation layer 12 is also grown in an island shape, similar to a circular truncated cone. With the increase of growth time, a value of P2/P1 decreases with the increase of a thickness of the nucleation layer 12, so that the islands in the nucleation layer 12 tend to merge to eventually merge into a film. In this embodiment, the thickness of the nucleation layer 12 is controlled to be 10 nm to 100 nm, so that the plurality of nucleation units 121 that are island-shaped may be formed, avoiding merging of each of the nucleation units 121 to form a film a film, and ensuring that a space is provided for the growth of the 3D buffer layer 131.

Specifically, if the thickness of the nucleation layer 12 is too small (for example, less than 10 nm), the value of P2/P1 is too large (for example, more than 3), resulting in a too small area of an upper surface of the nucleation unit 121, and further causing too few positions favorable for growth of the buffer layer 13, so that the buffer layer 13 continues to grow in 3D, which results in the inability to merge into a film. If the thickness of the nucleation layer 12 is too large (for example, more than 100 nm), the islands in the nucleation layer 12 merge into a film, resulting in the inability to form the nucleation units 121 that are island-shaped, which is not conducive to the 3D growth of the buffer layer 13. Preferably, 10 nm≤T1≤50 nm.

FIG. 2 is a schematic structural diagram of another epitaxial structure of a semiconductor device provided by an embodiment of the present disclosure. As shown in FIG. 2, optionally, the buffer layer 13 further includes a 2D buffer layer 132, and the 2D buffer layer 132 is located at a side, away from the nucleation layer 12, of the 3D buffer layer 131.

Specifically, the 2D buffer layer 132 refers to a buffer layer formed in a mode of 2D growth. During the 2D growth, the buffer layer 13 tends to grow in a stepped mode, with a flat surface. The buffer layer 13 is first grown along a direction parallel to the plane where the substrate 11 is located to form a planar thin film, and then is grown in stacks along a direction perpendicular to the plane where the substrate 11 is located. The mode of the 2D growth is a layer-by-layer growth, and each layer is a complete thin film.

In the related technologies, due to a thermal mismatch between GaN and a heterogeneous substrate, there is a difference in thermal expansion and cold contraction between the GaN and the heterogeneous substrate during high-temperature growth and a cooling process, which leads to a certain degree of warping in GaN epitaxy. When the degree of the warping is too large, subsequent processes is affected. In the embodiments of the present disclosure, the buffer layer 13 is set to include the 3D buffer layer 131 and the 2D buffer layer 132, so that a final degree of the warping in the epitaxial structure 1 may be controlled by adjusting thicknesses of the 3D buffer layer 131 and the 2D buffer layer 132.

Specifically, since a lattice constant of GaN is greater than that of AIN, the GaN (i.e., the buffer layer 13) grown on AIN or AlGaN (i.e., the nucleation layer 12) is subjected to a compressive stress, while during 3D growth, a tensile stress may be generated due to the merging of the islands, which can balance the compressive stress during the growth, so that the degree of the warping can be adjusted. Further, due to performance requirements of a semiconductor device, there is a certain requirement for a total thickness of the buffer layer 13. In the embodiments of the present disclosure, a thickness relationship between the 3D buffer layer 131 and the 2D buffer layer 132 is adjusted, so that the final degree of the warping in the epitaxial structure 1 may be controlled while the total thickness of the buffer layer 13 meets the requirement, making a surface of the epitaxial structure I tend to be flat.

Exemplarily, FIG. 3 to FIG. 5 are schematic diagrams showing a principle that an epitaxial structure of a semiconductor device according to an embodiment of the present disclosure has a small degree of warping. In FIG. 3 to FIG. 5, the abscissa represents growth time, and the ordinate represents degree of warping in the epitaxial structure 1. A curve above the horizontal axis indicates that a surface of the epitaxial structure 1 is a concave surface, and a curve below the horizontal axis indicates that a surface of the epitaxial structure 1 is a convex surface. The endpoint O to the endpoint D indicates a whole preparation process of the epitaxial structure 1, and a curve formed by connection of points indicates a change of the degree of the warping in the epitaxial structure 1. As shown in FIG. 3 to FIG. 5, a stage from the point O to the point A indicates a heating process of the substrate 11, and the substrate 11 becomes concave due to a temperature difference between an upper surface of the substrate 11 and a lower surface of the substrate 11 during heating. A stage from the point A to the point B indicates a growth process of the nucleation layer 12, and during the growth of the nucleation layer 12, the nucleation layer 12 is subjected to a compressive stress, and therefore, the degree of the warping is reduced, i.e., the warping develops towards a convex direction, but the warping is still in a concave state. A stage from the point B to the point C indicates a growth process of the buffer layer 13, and during the growth of the buffer layer 13 on the nucleation layer 12, since the buffer layer 13 is subjected to a compressive stress, the degree of the warping is reduced or even the warping is in a convex state. A stage from the point C to the point D indicates a cooling process, and during the cooling, due to a difference in an expansion coefficient between the substrate 11 and the GaN, the warping develops towards a concave direction.

Specifically, under a condition that the total thickness of the buffer layer 13 is certain, a change of the degree of the warping caused by the cooling process (i.e., the stage from the point C to the point D) is certain, and therefore, the final degree of the warping in the epitaxial structure 1 is determined by a warping value in the epitaxial structure 1 before cooling. In other words, if an absolute value of the warping value before cooling (i.e., the ordinate of the point C) is larger, the epitaxial structure 1 may be more convex after cooling. A principle for solving a warping problem in the epitaxial structure 1 according to the embodiments of the present disclosure may be explained with reference to FIG. 3 to FIG. 5.

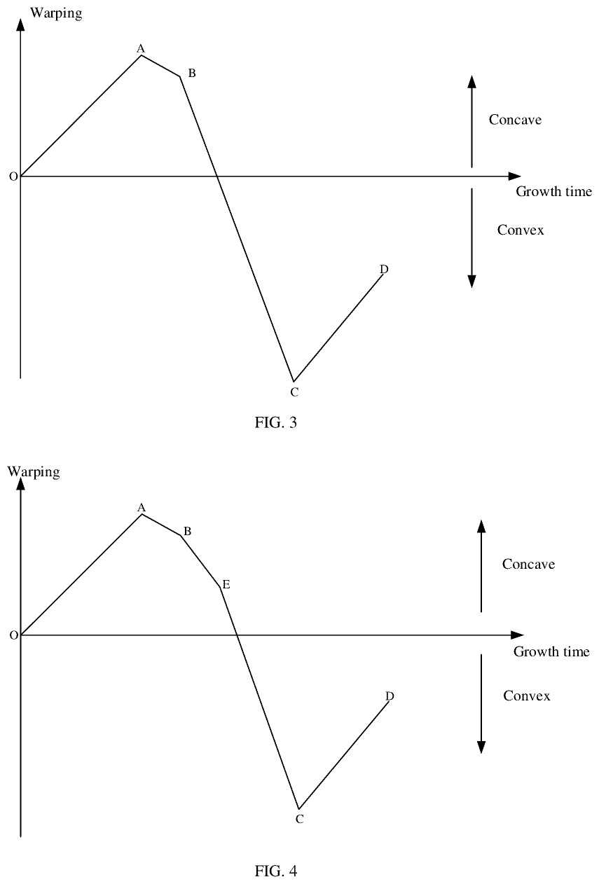

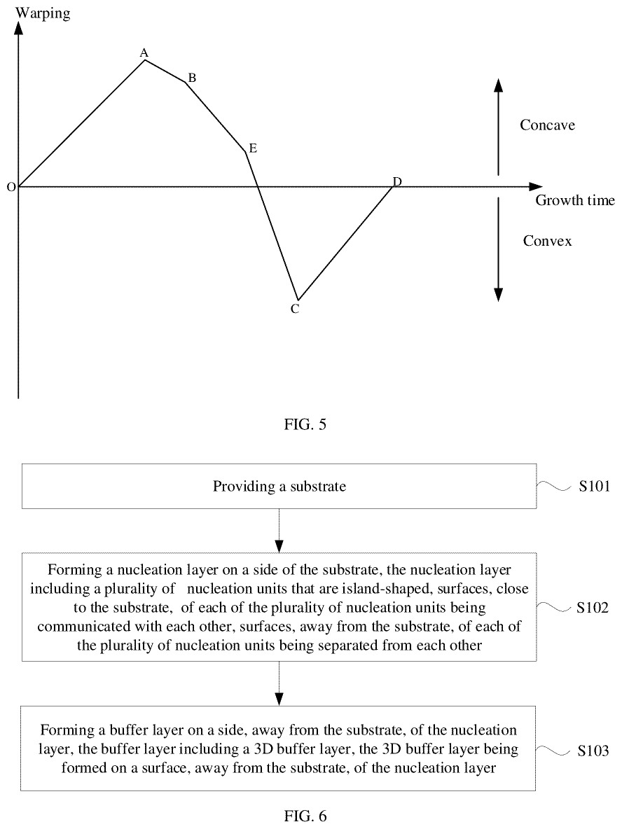

As for the growth process of the buffer layer 13, the differences between FIG. 3 to FIG. 5 lie in that a curve shown in FIG. 3 corresponds to the buffer layer 13 including the 2D buffer layer 132 with a thickness of 2 μm, a curve shown in FIG. 4 corresponds to the buffer layer including the 3D buffer layer 131 with a thickness of 0.5 μm and the 2D buffer layer 132 with a thickness of 1.5 μm, and a curve shown in FIG. 5 corresponds to the buffer layer 13 including the 3D buffer layer 131 with a thickness of 0.7 μm and the 2D buffer layer 132 with a thickness of 1.3 μm. The total thicknesses of the buffer layer 13 in three embodiments are equal. By comparing FIG. 3, FIG. 4 and FIG. 5, it can be seen that compared with a process of the 2D growth, since a tensile stress is generated in the buffer layer during the process of the 3D growth (i.e., the stage from the point B to the point E), the tensile stress can balance the compressive stress during growth, making the epitaxial structure 1 develop towards a convex direction at a relatively low speed. Therefore, the thickness of the 3D buffer layer 131 is increased, and the thickness of the 2D buffer layer 132 is appropriately decreased, so that the absolute value of the warping before cooling may be reduced, reducing the final degree of the warping in the epitaxial structure 1, and even making the epitaxial structure 1 tend to be flat. At the same time, the thickness relationship between the 3D buffer layer 131 and the 2D buffer layer 132 is adjusted, so that the total thickness of the buffer layer 13 is ensured to meet design requirements while the warping problem in the epitaxial structure 1 may be solved, avoiding the inability of a buffer layer with a single type to simultaneously make the total thickness of the buffer layer 13 and the degree of the warping in the epitaxial structure 1 meet standards.

In a specific embodiment, referring to FIG. 2, the thickness of the 3D buffer layer 131 is defined as T2, the thickness of the 2D buffer layer 132 is defined as T3, and T2 and T3 may satisfy ¼≤T2/(T2+T3)≤½. When the thickness of the 3D buffer layer 131 is ¼ to ½ of the total thickness of the buffer layer 13, the warping problem in the epitaxial structure 1 may be effectively solved, improving quality of the epitaxial structure 1, and further ensuring quality of a semiconductor device. Exemplarily, the total thickness of the buffer layer 13 (i.e., T2+T3) may set to satisfy 0.1 μm≤T2+T3≤10 μm. This thickness range is merely an example, not a limitation, and a person skilled in the art can design the total thickness of the buffer layer 13 according to requirements.

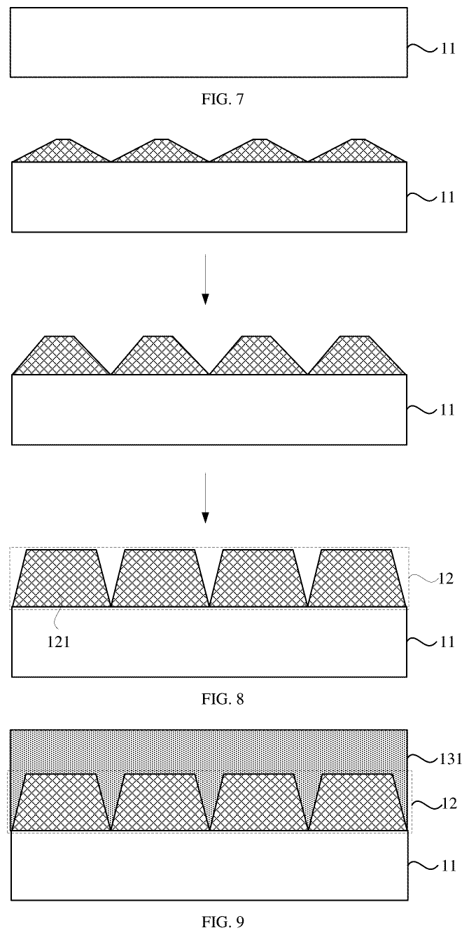

Based on a same inventive concept, embodiments of the present disclosure also provide a preparing method for an epitaxial structure of a semiconductor device, which is applied to prepare the epitaxial structure 1 provided by any of the above embodiments above-mentioned. FIG. 6 is a flowchart of a preparing method for an epitaxial structure of a semiconductor device according to an embodiment of the present disclosure, and FIG. 7 to FIG. 9 are schematic diagrams of intermediate structures generated during a preparation process of the preparing method shown in FIG. 6. As shown in FIG. 6, the preparing method includes the following steps.
S101, providing a substrate.

As shown in FIG. 7, a substrate 11 is provided. Exemplarily, a material of the substrate 11 may be SiC. In addition, in this step, the substrate 11 may be heat-treated.
S102, forming a nucleation layer on a side of the substrate, the nucleation layer including a plurality of nucleation units that are island-shaped, surfaces, close to the substrate, of each of the plurality of nucleation units being communicated with each other, surfaces, away from the substrate, of each of the plurality of nucleation units being separated from each other.

Exemplarily, the nucleation layer may be an AIN nucleation layer or an AlGaN nucleation layer. FIG. 8 schematically shows a growth process of the nucleation layer 12 on the substrate 11. As can be seen from FIG. 8, the nucleation layer 12 is grown in an island shape, and with the increase of a thickness of the nucleation layer 12, the islands tend to merge into a film. The thickness of the nucleation layer 12 is reasonably controlled, so that the nucleation layer 12 may include the plurality of nucleation units 121, the surfaces, close to the substrate 11, of each of nucleation units 121 are communicated with each other, and the surfaces, away from the substrate 11, of each of the nucleation units 121 are separated from each other.
S103, forming a buffer layer on a side, away from the substrate, of the nucleation layer, the buffer layer including a 3D buffer layer, the 3D buffer layer being formed on a surface, away from the substrate, of the nucleation layer.

Exemplarily, the buffer layer may specifically be a GaN buffer layer. As shown in FIG. 9, the 3D buffer layer 131 is formed on the surface, away from the substrate 11, of the nucleation layer 12. The 3D buffer layer is formed, so that crystal quality may be improved. Moreover, in this embodiment, the nucleation layer 12 includes the plurality of nucleation units 121 that are island-shaped, which is more conducive to 3D growth of the buffer layer 13, so that dislocations are bent and annihilated during the 3D growth of the buffer layer 13, improving crystal quality of GaN, and further ensuring quality of a semiconductor device.

In the preparing method for the epitaxial structure of the semiconductor device provided by the embodiments of the present disclosure, the nucleation layer is formed, so that the nucleation layer includes the plurality of nucleation units that are island-shaped, the surfaces, close to the substrate, of each of the plurality of nucleation units are communicated with each other, and the surfaces, away from the substrate, of each of the plurality of nucleation units are separated from each other, which is beneficial to the growth of the 3D buffer layer, so that dislocations may be bent and annihilated during the 3D growth of the buffer layer, improving crystal quality of GaN, and further ensuring quality of a semiconductor device.

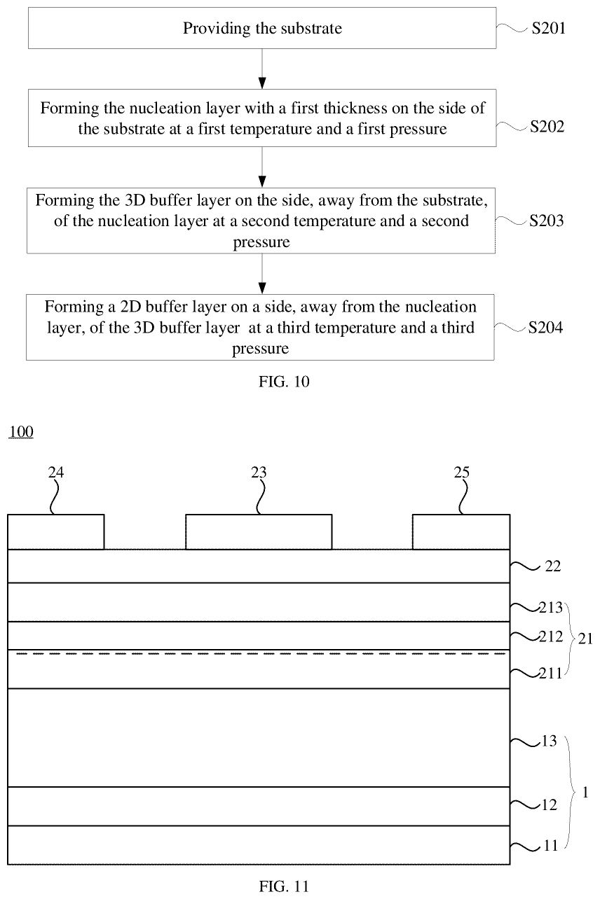

On the basis of the above-mentioned embodiments, further, FIG. 10 is a flowchart of another preparing method for an epitaxial structure of a semiconductor device according to an embodiment of the present disclosure. Further refinement and improvement are made to the preparation of the nucleation layer and the buffer layer. As shown in FIG. 10, the preparing method may include the following steps.
S201, providing the substrate.
S202, forming the nucleation layer with a first thickness on the side of the substrate at a first temperature and a first pressure.

Optionally, the first temperature ranges from 1050° C. to 1200° C., the first pressure ranges from 50 mbar to 150 mbar, and along a direction perpendicular to a plane where the substrate is located, the first thickness ranges from 10 nm to 100 nm.

Under the first temperature and the first pressure within this range, the nucleation layer may be grown in the island shape. The thickness of the nucleation layer is controlled to range from 10 nm to 100 nm, which may not only form the nucleation units that are island-shaped, but also ensure that a space is provided for the growth of the 3D buffer layer. The principle thereof may not be described in detail herein, but may be referred to the description of the embodiments of the epitaxial structure above-mentioned.
S203, forming the 3D buffer layer on the side, away from the substrate, of the nucleation layer at a second temperature and a second pressure.

Optionally, the second temperature ranges from 1000° C. to 1080° C., and the second pressure ranges from 150 mbar to 600 mbar. Taking the buffer layer being a GaN buffer layer as an example, in high-pressure environment above-mentioned, and under influence of a morphology of the nucleation layer, GaN is more likely to grow in 3D, and merge into a film with the increase of the thickness of the buffer layer, so as to form the 3D buffer layer.
S204, forming a 2D buffer layer on a side, away from the nucleation layer, of the 3D buffer layer at a third temperature and a third pressure.

The third temperature ranges from 1000° C. to 1080° C., and the third pressure ranges from 50 mbar to 150 mbar. As shown in FIG. 2, the 2D buffer layer 132 is formed on the side, away from the nucleation layer 12, of the 3D buffer layer 131. In low-pressure environment above-mentioned, GaN is grown in 2D, so as to form the 2D buffer layer.

In the embodiments of the present disclosure, the 2D buffer layer 132 is formed on the side, away from the nucleation layer 12, of the 3D buffer layer 131, and a thickness relationship between the 3D buffer layer 131 and the 2D buffer layer 132 is adjusted, so that a final degree of warping in the epitaxial structure 1 may be controlled while a total thickness of the buffer layer 13 meets design requirements. The specific principle is not repeated herein.

Exemplarily and optionally, along a direction perpendicular to a plane where the substrate is located. a thickness of the 3D buffer layer is T2, and a thickness of the 2D buffer layer is T3, which satisfies ¼≤T2/(T2+T3)≤½.

As a feasible embodiment, the following provides a main preparing process of an epitaxial structure, which is capable to obtain an epitaxial structure with good crystal quality of GaN and a small degree of warping.

First, a SiC substrate is heated to 1100° C. in H2environment, and then the SiC substrate is heat-treated for 10 min at this temperature.

Then, under a condition that the temperature is 1100° C. and a pressure is 100 mbar, with a flow rate of 14.5 μmol/min for an Al source and a flow rate of 45 mol/min for a N source, an AIN nucleation layer with a thickness of 50 nm is formed on a side of the substrate.

Next, the temperature is reduced to 1050° C., and under a condition that a pressure is 200 mbar, with a flow rate of 252 μmol/min for a Ga source and a flow rate of 76 mmol/min for a N source, a 3D buffer layer with a thickness of 0.7 μm is formed, and then the pressure is reduced to 100 mbar, with a flow rate of 252 μmol/min for a Ga source and a flow rate of 76 mmol/min for a N source, a 2D buffer layer with a thickness of 1.3 μm is formed.

Subsequently, a heterojunction structure is formed on the epitaxial structure through secondary growth, and a gate, a source and a drain are formed on a side, away from the substrate, of the heterojunction structure, so that the preparation of the semiconductor device may be completed. This is not described in detail in the embodiments of the present disclosure, and may be designed by a person skilled in the art.

Based on a same inventive concept, embodiments of the present disclosure further provide a semiconductor device. FIG. 11 is a schematic structural diagram of a semiconductor device according to an embodiment of the present disclosure. As shown in FIG. 11, the semiconductor device 100 includes the epitaxial structure 1 provided by any of the embodiments above-mentioned, and further includes a heterojunction structure 21 located at a side, away from the substrate 11, of the epitaxial structure 1, and a gate 23, a source 24 and a drain 25 located at a side, away from the substrate 11, of the heterojunction structure 21. The gate 23 is located between the source 24 and the drain 25. Since the semiconductor device 100 includes the epitaxial structure 1 provided by any of the embodiments above-mentioned, the semiconductor device 100 has the same beneficial effects as the epitaxial structure 1. The similarities may be referred to the description of the embodiments of the epitaxial structure 1 above-mentioned, which is not repeated herein.

Referring to FIG. 11, the heterojunction structure 21 includes a channel layer 211 (GaN) and a barrier layer 213 (AlGaN). The barrier layer 213 is located on a side, away from the epitaxial structure 1, of the channel layer 211. A two-dimensional electron gas (2DEG) is formed on a side, close to the barrier layer 213, of the channel layer 211 (shown by the dotted line in FIG. 11).

In addition, as shown in FIG. 11, the semiconductor device 100 may further include a cap layer 22 (GaN) located at a side, away from the substrate 11, of the barrier layer 213, and the heterojunction structure 21 may further include an insertion layer 212 (AlN) located between the channel layer 211 and the barrier layer 213, so as to improve performance of a semiconductor device.

Optionally, materials of the source 24 and the drain 25 may be one or more combinations of metals such as Ni, Ti, Al or Au, and a material of the gate 23 may be one or more combinations of metals such as Ni, Pt, Pb or Au.

It should be understood that, in the embodiments of the present disclosure, reliability of a semiconductor device is improved from a perspective of a design of an epitaxial structure of the semiconductor device. The semiconductor device includes, but is not limited to, a gallium nitride High Electron Mobility Transistor (HEMT) having high-power and operating in high voltage and high current environments, a transistor with a structure of Silicon-On-Insulator (SOI), a gallium arsenide (GaAs)-based transistor, a Metal-Oxide-Semiconductor Field-Effect Transistor (MOSFET), a Metal-Insulated-Semiconductor Field-Effect Transistor (MISFET), a Double Heterojunction Field-Effect Transistor (DHFET), a Junction Field-Effect Transistor (JFET), a Metal-Semiconductor Field-Effect Transistor (MESFET), a Metal-Insulated-Semiconductor Heterojunction Field-Effect Transistor (MISHFET) or other field-effect transistors.

It should be noted that, the above-mentioned is merely the preferred embodiments of the present disclosure and the applied technical principles. It will be understood by a person skilled in the art that the present disclosure is not limited to the specific embodiments described herein, and various obvious changes, readjustments and substitutions can be made by a person skilled in the art without departing from the protection scope of the present disclosure. Therefore, although the present disclosure has been described in detail through the above-mentioned embodiments, the present disclosure is not limited to the above-mentioned embodiments, but may include many other equivalent embodiments without departing from the concept of the present disclosure, and the scope of the present disclosure is determined by the scope of the appended claims.

What is Claimed is:

1. An epitaxial structure of a semiconductor device, comprising:
a substrate;
a nucleation layer located at a side of the substrate, the nucleation layer comprising a plurality of nucleation units, surfaces, close to the substrate, of the plurality of nucleation units being communicated with each other, and surfaces, away from the substrate, of the plurality of nucleation units being separated from each other; and
a buffer layer located at a side, away from the substrate, of the nucleation layer, the buffer layer comprising a three-dimensional (3D) buffer layer, and the 3D buffer layer being formed on a surface, away from the substrate, of the nucleation layer.

2. The epitaxial structure according to claim 1, wherein a first cross section of a nucleation unit is perpendicular to a plane where the substrate is located, and a shape of the first cross section is trapezoid.

3. The epitaxial structure according to claim 2, wherein the first cross section comprises a first edge and a second edge along a direction perpendicular to a plane where the substrate is located, the first edge is located at a side, away from the substrate, of the second edge, a length of the first edge is P1, and a length of the second edge is P2, where 1<P2/P1≤3; and
along the direction perpendicular to the plane where the substrate is located, a distance between the first edge and the second edge is T1, where 10 nm≤T1≤100 nm.

4. The epitaxial structure according to claim 1, wherein the buffer layer further comprises a two-dimensional (2D) buffer layer, and the 2D buffer layer is located at a side, away from the nucleation layer, of the 3D buffer layer.

5. The epitaxial structure according to claim 4, wherein along a direction perpendicular to a plane where the substrate is located, a thickness of the 3D buffer layer is T2, and a thickness of the 2D buffer layer is T3, where ¼≤T2/(T2+T3)≤½.

6. The epitaxial structure according to claim 5, wherein 0.1 μm≤T2+T3≤10 μm.

7. The epitaxial structure according to claim 1, wherein the 3D buffer layer is grown directly along a direction perpendicular to a plane where the substrate is located.

8. The epitaxial structure according to claim 4, wherein the 2D buffer layer is first grown in 2D along a direction parallel to a plane where the substrate is located to form a planar thin film, and then is grown in stacks along a direction perpendicular to the plane where the substrate is located.

9. The epitaxial structure according to claim 1, wherein a nucleation unit is island-shaped.

10. The epitaxial structure according to claim 1, wherein a material of the substrate is selected from one or more combinations of indium phosphide, gallium arsenide, silicon carbide, diamond, sapphire, germanium, silicon or a material that is heterogeneous with GaN and capable to grow group III nitrides.

11. A preparing method for an epitaxial structure of a semiconductor device, comprising:
providing a substrate;
forming a nucleation layer on a side of the substrate, the nucleation layer comprising a plurality of nucleation units, surfaces, close to the substrate, of the plurality of nucleation units being communicated with each other, and surfaces, away from the substrate, of the plurality of nucleation units being separated from each other; and
forming a buffer layer on a side, away from the substrate, of the nucleation layer, the buffer layer comprising a 3D buffer layer, and the 3D buffer layer being formed on a surface, away from the substrate, of the nucleation layer.

12. The preparing method according to claim 11, wherein the forming a nucleation layer on a side of the substrate comprises:
forming the nucleation layer with a first thickness on the side of the substrate at a first temperature and a first pressure, and the first thickness is a thickness along a direction perpendicular to a plane where the substrate is located; and the first temperature ranges from 1050° C. to 1200° C., the first pressure ranges from 50 mbar to 150 mbar, and the first thickness ranges from 10 nm to 100 nm.

13. The preparing method according to claim 11, wherein the forming a buffer layer on a side, away from the substrate, of the nucleation layer comprises:
forming the 3D buffer layer on the side, away from the substrate, of the nucleation layer at a second temperature and a second pressure; and the second temperature ranges from 1000° C. to 1080° C., and the second pressure ranges from 150 mbar to 600 mbar.

14. The preparing method according to claim 11, wherein the buffer layer further comprises a 2D buffer layer; and
the forming a buffer layer on a side, away from the substrate, of the nucleation layer comprises:
forming the 2D buffer layer on a side, away from the nucleation layer, of the 3D buffer layer at a third temperature and a third pressure; and the third temperature ranges from 1000° C. to 1080° C., and the third pressure ranges from 50 mbar to 150 mbar.

15. A semiconductor device, comprising an epitaxial structure;
wherein the epitaxial structure comprises:
a substrate;
a nucleation layer located at a side of the substrate, the nucleation layer comprising a plurality of nucleation units, surfaces, close to the substrate, of the plurality of nucleation units being communicated with each other, and surfaces, away from the substrate, of the plurality of nucleation units being separated from each other; and
a buffer layer located at a side, away from the substrate, of the nucleation layer, the buffer layer comprising a three-dimensional (3D) buffer layer, and the 3D buffer layer being formed on a surface, away from the substrate, of the nucleation layer;
wherein the semiconductor device further comprises a heterojunction structure located at a side, away from the substrate, of the epitaxial structure, and a gate, a source and a drain located at a side, away from the substrate, of the heterojunction structure, and the gate is located between the source and the drain.

16. The semiconductor device according to claim 15, wherein a first cross section of a nucleation unit is perpendicular to a plane where the substrate is located, and a shape of the first cross section is trapezoid.

17. The semiconductor device according to claim 16, wherein the first cross section comprises a first edge and a second edge along a direction perpendicular to a plane where the substrate is located, the first edge is located at a side, away from the substrate, of the second edge, a length of the first edge is P1, and a length of the second edge is P2, where 1<P2/P1≤3; and
along the direction perpendicular to the plane where the substrate is located, a distance between the first edge and the second edge is T1, where 10 nm≤T1≤100 nm.

18. The semiconductor device according to claim 15, wherein the buffer layer further comprises a two-dimensional (2D) buffer layer, and the 2D buffer layer is located at a side, away from the nucleation layer, of the 3D buffer layer.

19. The semiconductor device according to claim 18, wherein along a direction perpendicular to a plane where the substrate is located, a thickness of the 3D buffer layer is T2, and a thickness of the 2D buffer layer is T3, where ¼≤T2/(T2+T3)≤½.

20. The semiconductor device according to claim 19, wherein 0.1 μm≤T2+T3≤10 μm.
